(19) United States
(12) Patent Application Publication
(10) Pub. No.: US 2024/0234591 A9
(43) Pub. Date: Jul. 11, 2024

(54) Metal-Oxide-Semiconductor Capacitor

(71) Applicant: KYOCERA AVX Components Corporation, Fountain Inn, SC (US)

(72) Inventors: Ronald S. Demcko, Raleigh, NC (US); Cory Nelson, Simpsonville, SC (US); Marianne Berolini, Greer, SC (US); Jeff Borgman, Myrtle Beach, SC (US)

(21) Appl. No.: 18/489,042

(22) Filed: Oct. 18, 2023

Related U.S. Application Data
(60) Provisional application No. 63/418,110, filed on Oct. 21, 2022.

(51) Int. Cl. H01L 29/94

(52) U.S. Cl. CPC H01L 29/94

(57) ABSTRACT

A metal-oxide-semiconductor (MOS) capacitor can include a substrate comprising a semiconductor material, an oxide layer formed over a first surface of the substrate, a resistive layer formed over at least a portion of the oxide layer, and a conductive layer formed over at least a portion of the resistive layer. As such, the MOS capacitor can include a resistor and a capacitor formed in series with one another.

### RELATED APPLICATION

The present application is based upon and claims priority to U.S. Provisional Patent Application Ser. No. 63/418,110, having a filing date of Oct. 21, 2022, which is incorporated herein by reference.

### BACKGROUND OF THE INVENTION

Metal-oxide-semiconductor (MOS) capacitors provide a variety of benefits, such as temperature stability, generally high breakdown voltages, and low leakage currents. Generally, however, the frequency response of MOS capacitors can limit their end applications. Increasing the equivalent series resistance (ESR) could expand the application of MOS capacitors.

### SUMMARY OF THE INVENTION

In accordance with one embodiment of the present disclosure, a capacitor can include a substrate comprising a semiconductor material. The capacitor can include an oxide layer formed over a surface of the substrate and a resistive layer formed over at least a portion of the oxide layer. The capacitor can include a conductive layer formed over at least a portion of the resistive layer.

In accordance with another embodiment of the present disclosure, a capacitor can include a substrate comprising a semiconductor material. The substrate can have a first surface opposite a second surface. The capacitor can include an oxide layer formed over the first surface of the substrate; a resistive layer formed over at least a portion of the oxide layer; a first conductive layer formed over at least a portion of the resistive layer; and a second conductive layer formed over at least a portion of the second surface of the substrate. The resistive layer can have a thickness less than about 10 microns.

In accordance with another embodiment of the present disclosure, a method of forming a capacitor can include forming an oxide layer over a surface of a substrate comprising a semiconductor material; depositing a resistive layer over at least a portion of the oxide layer; and depositing a conductive layer over at least a portion of the resistive layer.

In accordance with another embodiment of the present disclosure, an embedded capacitor assembly can include a circuit board substrate having a mounting surface and a capacitor at least partially embedded within the circuit board substrate. The capacitor can include a substrate including a semiconductor material and having a first surface opposite a second surface. The capacitor can include an oxide layer formed over the first surface of the substrate and a resistive layer formed over at least a portion of the oxide layer. The capacitor can include a conductive layer formed over at least a portion of the resistive layer.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures, in which:

FIG. 1 is a perspective view of a capacitor according to aspects of the present disclosure;

FIG. 2A is a side view of a capacitor according to aspects of the present disclosure;

FIG. 2B is a side view of another capacitor according to aspects of the present disclosure;

FIG. 2C is a side view of yet another capacitor according to aspects of the present disclosure;

FIG. 2D is a top view of a capacitor according to aspects of the present disclosure;

FIG. 2E is a side view of the capacitor of FIG. 2D;

FIG. 3A is a perspective view of still another capacitor according to aspects of the present disclosure;

FIG. 3B illustrates the capacitor of FIG. 3A having an oxide layer within a first portion of a surface of a substrate of the capacitor and a second terminal within a second portion of the surface of the substrate;

FIG. 4 is a perspective view of a capacitor assembly including a capacitor and a mounting surface, such as a printed circuit board, according to aspects of the present disclosure;

FIG. 5A illustrates an embedded capacitor assembly including a capacitor embedded in a circuit board substrate according to aspects of the present disclosure;

FIG. 5B illustrates another embedded capacitor assembly including a capacitor embedded in a circuit board substrate according to aspects of the present disclosure;

FIG. 6A is an electrical diagram of a capacitor according to aspects of the present disclosure;

FIG. 6B is an electrical diagram of a high electron mobility transistor incorporating a plurality of capacitors according to aspects of the present disclosure;

FIG. 7 is a flowchart of a method for forming a capacitor according to aspects of the present disclosure; and

FIG. 8 is a graph illustrating the change in Q factor with changes in a ratio between resistor area and an area of a conductive layer.

Repeat use of reference characters in the present specification and drawings is intended to represent same or analogous features or elements of the invention.

### DETAILED DESCRIPTION OF REPRESENTATIVE EMBODIMENTS

It is to be understood by one of ordinary skill in the art that the present discussion is a description of exemplary embodiments only and is not intended as limiting the broader aspects of the present invention, which broader aspects are embodied in the exemplary construction.

Generally speaking, the present invention is directed to a metal-oxide-semiconductor (MOS) capacitor having a resistive layer. For example, the MOS capacitor (or simply “capacitor”) can include a substrate, an oxide layer formed over a surface of the substrate, a resistive layer formed over at least a portion of the oxide layer, and a conductive layer formed over at least a portion of the resistive layer. As described herein, an additional conductive layer formed or disposed opposite the oxide layer such that the substrate is disposed therebetween completes the capacitor.

An effective circuit formed by the MOS capacitor with the resistive layer is a resistor in line with a capacitor, which can render the MOS capacitor a higher equivalent series resistance (ESR) capacitor. Increased ESR can reduce the Q factor, or quality factor, of the capacitor and broaden the frequency response of the capacitor. A broadened frequency response of a MOS capacitor can improve the performance of bias lines in active radiofrequency (RF) devices, e.g., by providing filtered voltage to the active RF device. It will be appreciated that the quality factor or Q factor is the reactance of the capacitor divided by the ESR of the capacitor.

Additionally, or alternatively, a broadened frequency response due to increased ESR can enhance the performance of MOS capacitors in RF shunt applications and noise filtering applications. For example, a bias bank of RF active devices utilizing one or more MOS capacitors as described herein can have a reduced number of components, e.g., compared to a bias bank that does not utilize MOS capacitors having a resistive layer as described herein. A reduced number of components in the bias bank can increase reliability, reduce size, and improve active device performance of the bias bank. Other applications may include VCO, mixers, and cascade amplifiers voltage supply.

As stated, the MOS capacitor can include a substrate and an oxide layer formed over the substrate. The substrate of the MOS capacitor can include a semiconductor material, such as silicon, gallium arsenide, germanium, silicon carbide, strontium titanate, and/or mixtures thereof. The substrate can be doped with one or more suitable dopants, such as boron, arsenic, phosphorus, gallium, aluminum, indium, and antimony.

The oxide layer of the MOS capacitor can be formed over a surface of the substrate. The oxide layer can be or include silicon oxide and/or oxides of other example semiconductor materials described herein. The oxide layer can be grown in situ on the substrate. Lithography (e.g., photolithography) techniques can be used to define the shape of the oxide layer. For instance, portions of the oxide layer can be removed through etching such that the oxide layer is shaped as desired.

As used herein, a layer that is “formed over” an object can include the layer being directly formed on the object and the layer being formed over one or more intermediate layers that are between the layer and the object. Further, formed “over” a bottom surface refers to outward from a center of the component.

The surface of the substrate can generally be smooth. For example, the surface of the substrate can be free of pores, trenches, or the like. The oxide layer can have a generally uniform thickness over the surface of the substrate. For example, the thickness of the oxide layer can vary less than 20% across the oxide layer, in some embodiments less than 10%, and in some embodiments less than 5%.

The resistive layer of the MOS capacitor can be formed over at least a portion of the oxide layer. In some embodiments, the resistive layer may be a thin-film resistor. The thin-film resistor may be configured to exhibit a variety of resistance values, as desired. For example, in some embodiments the thin-film resistor may have a resistance that ranges from about 1Ω to about 2,000Ω, in some embodiments from about 2Ω to about 1,000Ω, in some embodiments from about 5Ω to about 750Ω, in some embodiments from about 10Ω to about 500Ω, in some embodiments from about 25Ω to about 400Ω.

The resistive layer of the thin-film resistor may be formed using a variety of thin film techniques as further described herein. The resistive layer of the thin-film resistor may be formed from a variety of suitable resistive materials. For example, the resistive layer may include tantalum nitride (TaN), silicon chromium (SiCr), nickel chromium (NiCr), tantalum aluminide, chromium silicon, titanium nitride, titanium tungsten, tantalum tungsten, oxides and/or nitrides of such materials, and/or any other suitable thin film resistive materials.

The conductive layer of the MOS capacitor can be formed over at least a portion of the resistive layer. The conductive layer can be contained within a perimeter of the oxide layer. The conductive layer can be free of direct contact and/or direct electrical connection with the substrate. The conductive layer can be or include metal, such as aluminum, copper, gold, silver, nickel, or mixtures thereof.

The MOS capacitor can also include an additional or a second conductive layer. For example, the conductive layer described above can be a first conductive layer and an additional conductive layer can be a second conductive layer, separate from the first conductive layer, that is formed over the substrate.

In some embodiments, the second conductive layer can be formed over a surface of the substrate opposite the oxide layer. For example, the substrate may have a first surface and a second surface opposite the first surface, and the oxide layer may be formed over the first surface and the second conductive layer may be formed over the second surface.

In other embodiments, the second conductive layer can be formed over the same surface of the substrate as the oxide layer. For example, the oxide layer can be formed over the first surface, and the second conductive layer also can be formed over the first surface. In such embodiments, the second conductive layer can be free of electrical connection to the oxide layer.

In some embodiments, the second conductive layer can be one terminal of a pair of terminals. For instance, the MOS capacitor can include a pair of terminals referred to individually as a first terminal and a second terminal. The first terminal can be connected with the first conductive layer. The second terminal can be connected with a surface of the substrate, such as the first surface (on which the oxide layer is formed) or the second surface (opposite the surface on which the oxide layer is formed). As used herein “connected with” can refer to components that are in direct physical contact. “Connected with” can also refer to items that are physically connected by one or intermediate conductive layers such that the items are in direct electrical connection (e.g., without a resistive layer or dielectric layer therebetween). For instance, the first terminal can be formed over the first conductive layer, and the second terminal can be formed over the first surface or the second surface of the substrate as described herein.

In other embodiments, rather than the second conductive layer being one terminal of a pair of terminals, the one terminal of the pair of terminals can be connected with the second conductive layer. For example, as described above, the MOS capacitor can include a pair of terminals referred to individually as a first terminal and a second terminal. The first terminal can be connected with the first conductive layer. The second terminal can be connected with the second conductive layer. For instance, the first terminal can be formed over the first conductive layer, and the second terminal can be formed over the second conductive layer.

One or more protective layers can be formed over the substrate. For example, where the oxide layer, resistive layer, and conductive layer are formed over a first surface of the substrate, one or more protective layers can be formed over a second surface of the substrate that is opposite the first surface. In some embodiments, the first and second terminals can be exposed through the one or more protective layers for electrical connection when surface mounting the capacitor. Example materials for the protective layer(s) include benzocyclobutene (BCB), polyimide, silicon oxynitride, alumina (Al2O3), silica (SiO2), silicon nitride (Si3N4), epoxy, glass, or another suitable material.

In some embodiments, the first and second terminals can be connected and arranged such that the oxide layer covers less than all of the first surface of the substrate. For example, the first terminal can be spaced apart from the second terminal in a Y-direction. An edge of the oxide layer can be aligned with an X-direction that is perpendicular to the Y-direction. An edge of the oxide layer can be spaced apart from an end of the substrate in the Y-direction.

The second terminal can be connected with the first surface of the substrate at a location that is spaced apart from the oxide layer along the first surface of the substrate. For example, the second terminal can be located between the edge of the oxide layer and the end of the substrate. The edge of the oxide layer can be spaced apart from the second terminal by a distance that is greater than about 2 microns, in some embodiments greater than about 5 microns, in some embodiments greater than about 10 microns, and in some embodiments greater than about 15 microns.

The oxide layer can cover a first portion of the first surface of the substrate that is distinct from a second portion of the first surface of the substrate that is free of the oxide layer. The second terminal can be connected with the first surface of the substrate within the second portion of the first surface of the substrate. The second terminal can include an electrically conductive material that directly contacts the first surface of the substrate.

As described herein, in other embodiments, the second terminal can be formed over the second surface of the substrate such that the substrate is disposed between the oxide layer and the second terminal. In some embodiments, the second terminal can include an electrically conductive material that directly contacts the second surface of the substrate, and in other embodiments, the second terminal can include an electrically conductive material that directly contacts a second conductive layer that is formed over the second surface of the substrate.

Various thin-film techniques can be used to form thin-film layers of the capacitor, such as the first conductive layer, the second conductive layer, the resistive layer, the terminals, or the like. Examples of such techniques that may be employed include chemical deposition (e.g., chemical vapor deposition), PECVD (Plasma Enhanced Chemical Vapor Deposition) processing, physical deposition (e.g., sputtering), or any other suitable deposition technique for forming thin-film elements. Additional examples include any suitable patterning technique (e.g., photolithography), etching, and any other suitable subtractive technique for forming thin-film elements.

The thin-film layers can have a range of thicknesses. For example, the thin-film layers can have thicknesses that can range in some embodiments from about 0.001 micrometers (microns) to about 100 microns, in some embodiments from about 0.0375 microns to about 40 microns, in some embodiments from about 0.1 microns to about 30 microns, in some embodiments from about 0.2 microns to about 20 microns in some embodiments from about 0.4 microns to about 10 microns. For instance, in some embodiments, the resistive layer may have a thickness less than about 10 microns, in some embodiments less than about 8 microns, in some embodiments less than about 6 microns, and in some embodiments less than about 4 microns.

In some embodiments, the conductive layer formed over the resistive layer may be relatively small compared to the resistive layer, which defines the capacitive area. By providing a relatively small conductive layer, only a relatively small area is available for current to flow through, which forces the current through the resistive layer and can increase resistance from the edges of the resistive layer to the relatively small conductive layer.

The relative size of the conductive layer compared to the resistive layer can be defined by a ratio of an area of the resistive layer to an area of the conductive layer. The area of the resistive layer can be defined by a length of the resistive layer that extends in the Y-direction and a width of the resistive layer that extends in the X-direction. Similarly, the area of the conductive layer can be defined by a length of the conductive layer that extends in the Y-direction and a width of the conductive layer that extends in the X-direction. In some embodiments, the ratio of the area of the resistive layer to the area of the conductive layer may be within a range of about 100:1, in some embodiments within a range of about 75:1, in some embodiments within a range of about 50:1, in some embodiments within a range of about 25:1, in some embodiments within a range of about 15:1, in some embodiments within a range of about 10:1, in some embodiments within a range of about 5:1, in some embodiments within a range of about 3:1, and in some embodiments within a range of about 1.5:1.

In some embodiments, each of the first terminal and the second terminal can be exposed along the same surface of the substrate for surface mounting the capacitor. Using surface mounting techniques, the MOS capacitor can be free of electrical connections, such as wirebond connections, that cause high frequency perturbations and adversely affect high frequency performance. As such, a surface mounted MOS capacitor can generally have excellent high frequency performance.

For example, the capacitor can be configured for grid array type mounting, such as land grid array, ball grid array, or the like. The terminals can be exposed along the first surface of the substrate and contained within a perimeter of the first surface of the monolithic substrate. As another example, the substrate can have a pair of end surfaces that are perpendicular to the first surface of the monolithic substrate. The pair of end surfaces can be free of terminations, including the terminals. As a further example, the first terminal, the second terminal, or both can be spaced apart from a pair of opposite end edges of the first surface of the monolithic substrate by respective distances. The distances can be 10 microns or greater, in some embodiments 15 microns or greater, in some embodiments 20 microns or greater, in some embodiments 40 microns or greater, and in some embodiments 50 microns or greater.

In some aspects of the present subject matter, the MOS capacitor can be configured for being embedded within a circuit board substrate, such as a printed circuit board. For example, the first terminal and the second terminal can be exposed along opposite surfaces of the substrate, such as a top surface and a bottom surface of the substrate and can be contained within a perimeter of the respective surface of the substrate. In other embodiments, the first terminal and the second terminal of the embedded capacitor can be exposed along the same surface of the substrate.

The present subject matter is further directed to an embedded capacitor assembly including a circuit board substrate, such as a printed circuit board, having a MOS capacitor at least partially embedded therein. The circuit board substrate can be formed from any suitable material, such as FR4, polytetrafluoroethylene, or the like. One or more electronic components, such as capacitors, resistors, transistors, switches, and/or other electronic components can be mounted to the circuit board substrate. As used herein, “mounted to” the circuit board can include any type of connection to the circuit board substrate that provides electrical connectivity, such as surface mounting to a surface of the circuit board substrate, embedding within the circuit board substrate, or the like.

In some embodiments, the circuit board substrate can have a recessed opening in a mounting surface of the circuit board substrate, such as an upper surface or a lower surface. The recessed opening can be configured to receive an electric component to be embedded within the circuit board substrate. For instance, a capacitor, such as the capacitors described herein, can be inserted within the recessed opening for embedding within the circuit board substrate. One or more electrically conductive terminations of the capacitor can be coupled to the circuit board substrate. For instance, one or more vias can be formed in, on, or through the terminations to electrically connect the capacitor with one or more conductive traces of the circuit board substrate and/or one or more electronic components that are mounted to the circuit board substrate.

The first and second terminals of the capacitor can be formed from copper, such as by copper plating. Typically, solid copper may not be a suitable material for forming exposed terminations of an electronic component because copper is susceptible to oxidizing when exposed. As such, solder material such as an alloy of copper, tin, and gold, is often used to form electrical terminations for electronic components such as capacitors. However, the present inventors have found that forming the first and second terminals of the embeddable capacitor from copper, e.g., by plating solid copper over a conductive layer and/or over one or more surfaces of the substrate, can provide superior electrical connections without the risk of oxidizing when the capacitor is embedded within a circuit board substrate. For instance, the first and second terminals can be laser drilled to form direct electrical connections with the circuit board substrate and/or additional electronic components mounted to the circuit board substrate.

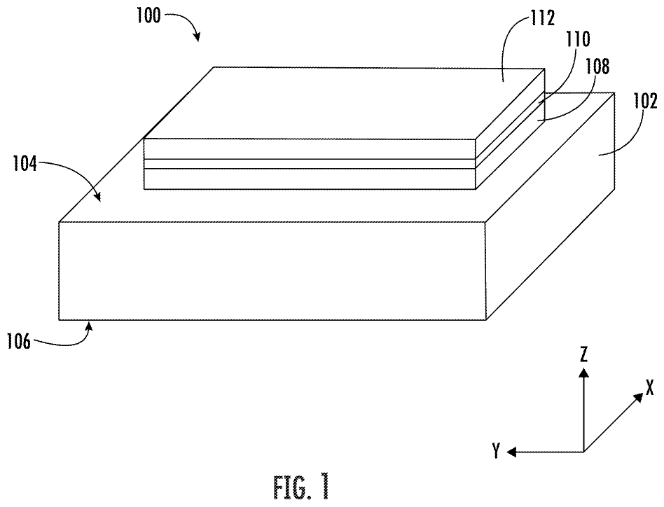

FIG. 1 is a perspective view of a capacitor 100 according to aspects of the present disclosure. The capacitor 100 can include a substrate 102 including a semiconductor material, such as silicon. The substrate 102 can have a first surface 104 and a second surface 106 opposite the first surface 104.

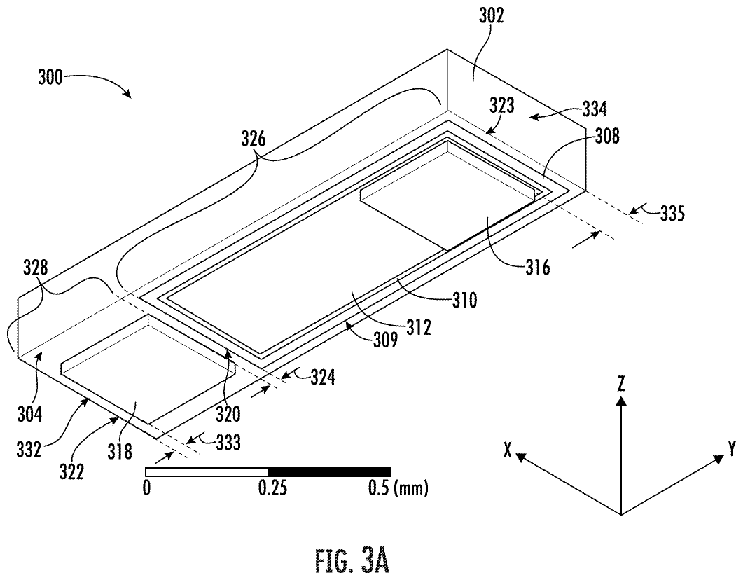

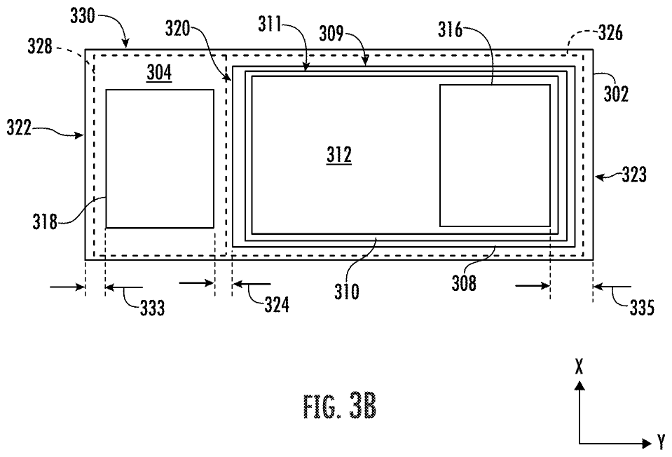

The capacitor 100 can include an oxide layer 108 formed over the first surface 104 of the substrate 102. The oxide layer 108 can include silicon oxide. The capacitor 100 can include a resistive layer 110 formed over at least a portion of the oxide layer 108. The resistive layer 110 can be contained within a perimeter of the oxide layer 108 (FIGS. 3A, 3B). The resistive layer 110 can be free of direct contact and/or direct electrical connection with the substrate 102.

In some embodiments, the resistive layer 110 can have a thickness less than about 10 microns. In some embodiments, the resistive layer 110 can be formed from tantalum nitride, and in other embodiments, the resistive layer 110 can be formed from chromium silicon. The resistive layer 110 can have other thicknesses and/or be formed from other materials as described elsewhere herein.

The capacitor 100 can further include a conductive layer 112 formed over at least a portion of the resistive layer 110. Like the resistive layer 110, the conductive layer 112 can be contained within the perimeter of the oxide layer 108, as well as a perimeter of the resistive layer 110 (FIGS. 3A, 3B). The conductive layer 112 can be free of direct contact and/or direct electrical connection with the substrate 102. Further, the conductive layer 112 can be free of direct contact and/or direct electrical connection with the oxide layer 108.

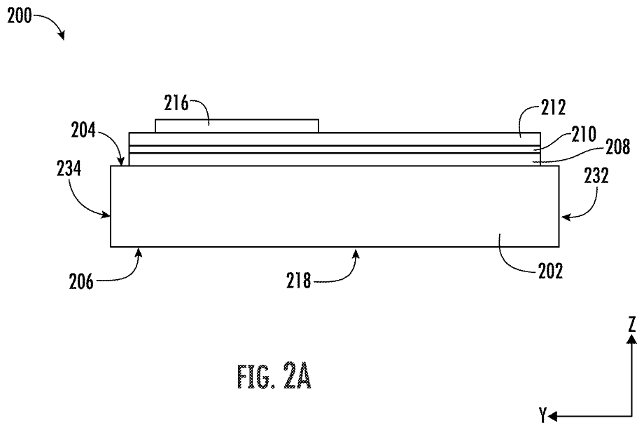

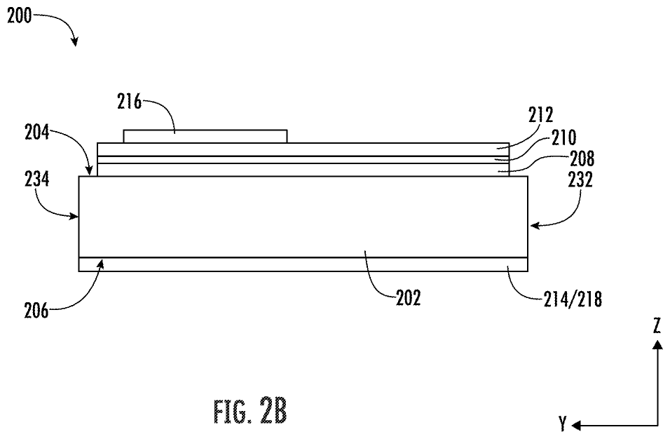

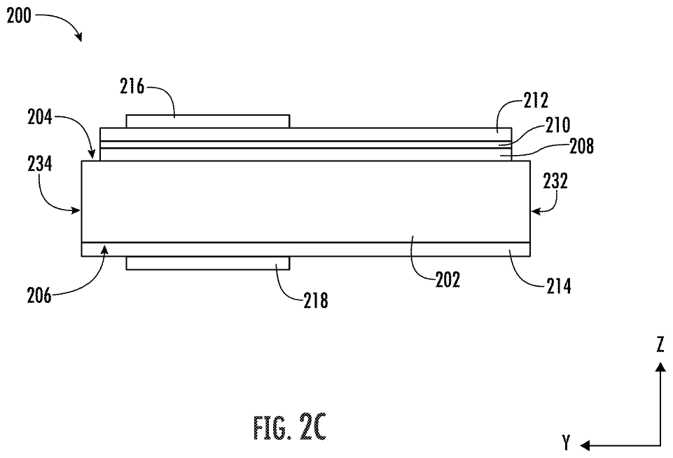

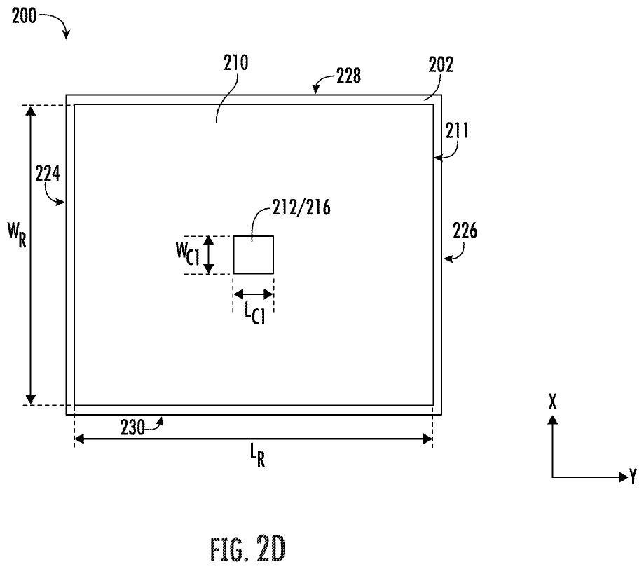

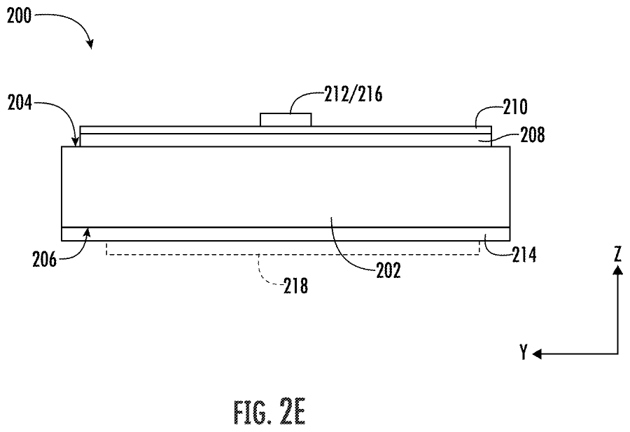

Referring to FIGS. 2A through 2C, side views are provided of various embodiments of a capacitor 200 according to aspects of the present disclosure. Similar reference numerals are used in FIGS. 2A through 2C as FIG. 1. For example, the capacitor 200 includes a substrate 202 including a semiconductor material, with an oxide layer 208 formed over a first surface 204 of the substrate 202. A resistive layer 210 is formed over at least a portion of the oxide layer 208, and a first conductive layer 212 is formed over at least a portion of the resistive layer 210.

In the embodiments shown in FIGS. 2B and 2C, a second conductive layer 214 is formed over a second surface 206 of the substrate 202, with the second surface 206 opposite the first surface 204. The second conductive layer 214 can extend over the entirety of the second surface 206 as shown in FIGS. 2B and 2C. Alternatively, the second conductive layer 214 could be offset from one or more edges of the substrate 202, e.g., similar to the oxide layer 208, resistive layer 210, and first conductive layer 212 formed over the first surface 204 of the substrate 202, such that the second conductive layer 214 extends over a portion of the second surface 206.

A pair of terminals can be connected with the capacitor. Each terminal of the pair of terminals can include an electrically conductive material, such as gold, copper, another suitable metal, or other conductive material. In some embodiments, at least one of the first conductive layer 212 or the second conductive layer 214 is one terminal of a pair of terminals. For example, the first conductive layer 212 and the second conductive layer 214 each may form a respective one terminal of a pair of terminals.

In other embodiments, only one of the first conductive layer 212 or the second conductive layer 214 may form one terminal of a pair of terminals, and in still other embodiments, neither the first conductive layer 212 nor the second conductive layer 214 may form a terminal of a pair of terminals. For instance, as shown in FIGS. 2A through 2C, a first terminal 216 of the pair of terminals can be connected with the first conductive layer 212.

Further, the first terminal 216 can be located closer to one end surface 234 of a pair of end surfaces 232, 234 of the substrate 202 than the other end surface 232 of the pair of end surfaces 232, 234. For example, the substrate can include a first end surface 232 and a second end surface 234 that are opposite one another along the Y-direction and are perpendicular to the first surface 204 and second surface 206 of the substrate 202. As shown in FIGS. 2A through 2C, the first terminal 216 can be disposed closer to the second end surface 234 than the first end surface 232. In other embodiments, the first terminal 216 can be disposed closer to the first end surface 232 than the second end surface 234. In still other embodiments, the first terminal 216 may be disposed equidistant from the first end surface 232 and the second end surface 234 along the Y-direction.

A second terminal 218 of the pair of terminals can be connected with the substrate 202 or the second conductive layer 214. For example, the capacitor 200 can include the second terminal 218 on the second surface 206 of the substrate 202. As shown in FIG. 2A, the second terminal 218 can be formed by the bare material of the second surface 206 of the substrate 202. Alternatively, referring to FIG. 2B, the second terminal 218 can be formed from the second conductive layer 214 formed over the second surface 206 of the substrate 202, which is opposite the first surface 204 in the Z-direction. Referring to FIG. 2C, in other embodiments, the second terminal 218 can be formed over the second conductive layer 214, such that the second conductive layer 214 is disposed between the second terminal 218 and the substrate 202. The second terminal 218 may be aligned with the first terminal 216 in the Z-direction, as shown in FIG. 2C, or the second terminal 218 may be offset from the first terminal 216 in the Z-direction. For instance, the second terminal 218 may be formed closer to the first end surface 232 than the second end surface 234. In any of these configurations, the oxide layer 208 is connected in series between the first conductive layer 212 and the second conductive layer 214 to form a capacitor between the first terminal 216 and the second terminal 218.

In still other embodiments, each of the second conductive layer 214 and the second terminal 218 can be formed over the second surface 206 of the substrate 202, without the second terminal 218 being formed over the second conductive layer 214, e.g., the second conductive layer 214 can be formed over one portion of the second surface 206 and the second terminal 218 can be formed over another, separate portion of the second surface 206.

In any event, the pair of terminals 216, 218, whether formed separately from the first conductive layer 212 and the second conductive layer 214 or formed by the first conductive layer 212 and/or the second conductive layer 214, are connected to various layers or the substrate 202 of the capacitor 200 such that the capacitor 200 includes a resistor and a capacitor formed in series with one another.

Turning now to FIGS. 2D and 2E, a top view and a side view, respectively, are provided of the capacitor 200 according to further aspects of the present disclosure. As previously described, the first conductive layer 212 can be contained within a perimeter 211 of the resistive layer 210 (which, in turn, can be contained within a perimeter 209 of the oxide layer 208). In the embodiment illustrated in FIG. 2D, the first conductive layer 212, which in some embodiments can form the first terminal 216, is relatively small compared to the resistive layer 210, which defines the capacitive area. By providing a relatively small first conductive layer 212, only a relatively small area is available for current to flow through, which forces the current through the resistive layer 210.

The relative size of the first conductive layer 212 compared to the resistive layer 210 may be defined by a ratio of an area of the resistive layer 210 to an area of the first conductive layer 212. The area of the resistive layer 210 can be defined by a length L_{R} of the resistive layer 210 that extends in the Y-direction between a first end edge 224 and a second end edge 226 of the substrate 202 and a width WR of the resistive layer 210 that extends in the X-direction between a first side edge 228 and a second side edge 230 of the substrate 202. Similarly, the area of the first conductive layer 212 can be defined by a length L_{C1} of the first conductive layer 212 that extends in the Y-direction and a width W_{C1} of the first conductive layer 212 that extends in the X-direction. In some embodiments, the ratio of the area of the resistive layer 210 to the area of the first conductive layer 212 may be within a range of about 100:1, in some embodiments within a range of about 75:1, in some embodiments within a range of about 50:1, in some embodiments within a range of about 25:1, in some embodiments within a range of about 15:1, in some embodiments within a range of about 10:1, in some embodiments within a range of about 5:1, in some embodiments within a range of about 3:1, and in some embodiments within a range of about 1.5:1.

Referring now to FIGS. 3A and 3B, a perspective bottom view and a bottom view are provided of a capacitor 300 according to aspects of the present disclosure. Similar reference numerals are used in FIGS. 3A and 3B as in FIGS. 1 and 2. For example, the capacitor 300 includes a substrate 302 including a semiconductor material, with an oxide layer 308 formed over a first surface 304 of the substrate 302. A resistive layer 310 is formed over at least a portion of the oxide layer 308, and a conductive layer 312 is formed over at least a portion of the resistive layer 310. The resistive layer 310 can be contained within a perimeter 309 of the oxide layer 308, and the conductive layer 312 can be contained within a perimeter 311 of the resistive layer 310.

In the embodiment shown in FIGS. 3A and 3B, each of a first terminal 316 and a second terminal 318 can be exposed along the first surface 304 of the substrate 302 for surface mounting the capacitor 300. The first terminal 316 can be formed over the conductive layer 312. The first terminal 316 can be spaced apart from the second terminal 318 in a Y-direction. An edge 320 of the oxide layer 308 can be aligned with an X-direction that is perpendicular to the Y-direction. The edge 320 of the oxide layer 308 can be spaced apart from an end edge 322 of the substrate 302 in the Y-direction.

The second terminal 318 can be co-planar with the oxide layer 308. For example, each of the second terminal 318 and the oxide layer 308 can be formed exclusively on the first surface 304 of the substrate 302. The second terminal 318 can be connected with the first surface 304 of the substrate 302 at a location that is spaced apart from the oxide layer 308 along the first surface 304 of the substrate 302. For instance, the second terminal 318 can be located between the edge 320 of the oxide layer 308 and the end 322 of the substrate 302. The edge 320 of the oxide layer 308 can be spaced apart from the second terminal 318 by a distance 324. In some embodiments, the distance 324 can be greater than about 2 microns.

Referring still to FIGS. 3A and 3B, the oxide layer 308 can be formed within a first portion 326 of the first surface 304 of the substrate 302. The first portion 326 of the first surface 304 of the substrate 302 can be distinct from a second portion 328 of the first surface 304 of the substrate 302. The second portion 328 of the first surface 304 can be free of the oxide layer 308.

The second terminal 318 can be connected with the first surface 304 of the substrate 302 within the second portion 328 of the first surface 304 of the substrate 302. In some embodiments, the second terminal 318 can directly contact the first surface 304 of the substrate 302. However, in other embodiments, the second terminal 318 can be electrically connected with the first surface 304 of the substrate 302 via one or more suitable conductive layers between the second terminal 318 and the first surface 304. In any event, the pair of terminals 316, 318 are connected to various layers or the substrate 302 of the capacitor 300 such that the capacitor 300 includes a resistor and a capacitor formed in series with one another.

Each of the first terminal 316 and the second terminal 318 can include an electrically conductive material, such as gold, copper, another suitable metal, or other conductive material. The substrate 302 can include a semiconductor material, such as silicon. The oxide layer 308 can include silicon oxide.

The capacitor 300 can be configured for grid array type mounting, such as ball grid array type mounting or land grid array type mounting. The terminals 316, 318 can be exposed along the first surface 304 and contained within a perimeter 330 of the first surface 304 of the monolithic substrate 302 in an X-Y plane lying in each of the X-direction and the Y-direction.

As another example, the substrate 302 can have a pair of end surfaces 332, 334 that are perpendicular to the first surface 304 of the monolithic substrate 302. The pair of end surfaces 332, 334 can be free of terminations, including the terminals 316, 318. As a further example, the first terminal 316, the second terminal 318, or both can be spaced apart from the pair of opposite end edges 322, 323 of the first surface 304 of the monolithic substrate 302 by respective distances 333, 335. The distances 333, 335 can be 10 microns or greater. Further, the distances 333, 335 can be equal to one another or different from one another, e.g., one of the distances 333, 335 can be greater than the other of the distances 333, 335.

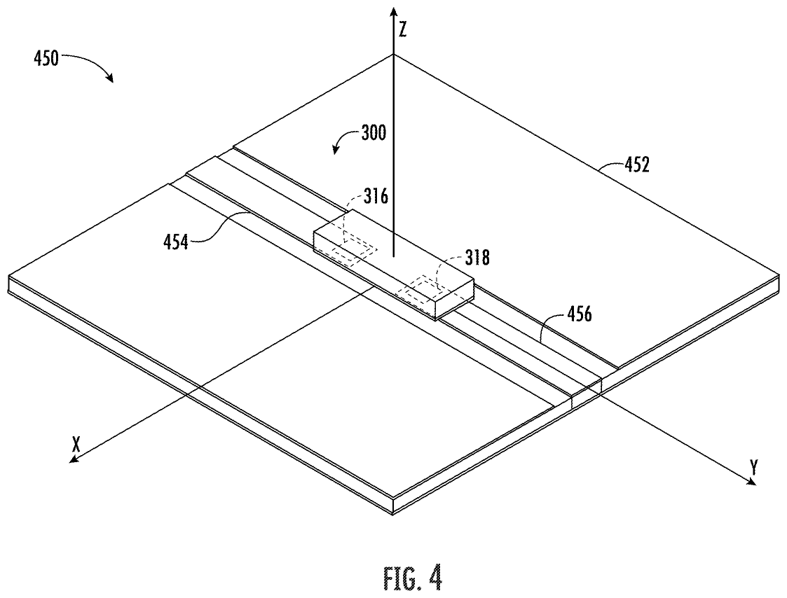

FIG. 4 is a perspective view of a capacitor assembly 450 including the capacitor 300 of FIGS. 3A and 3B and a mounting surface 452, such as a printed circuit board. The first terminal 316 of the capacitor 300 can be connected with a first conductive trace 454 of the mounting surface 452. The second terminal 318 of the capacitor 300 can be connected with a second conductive trace 456 of the mounting surface 452. As shown in FIG. 4, the capacitor 300 can be configured as a flip chip such that the first surface 304 (FIGS. 3A, 3B) is opposite the mounting surface 452.

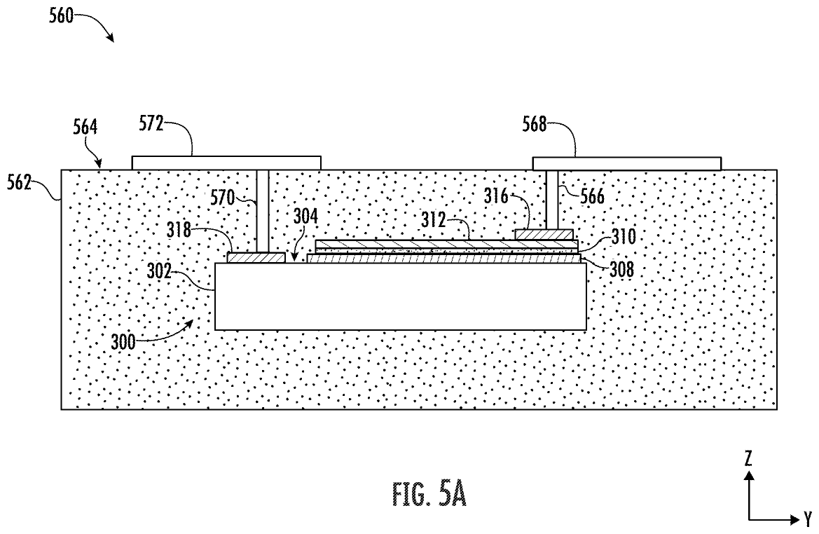

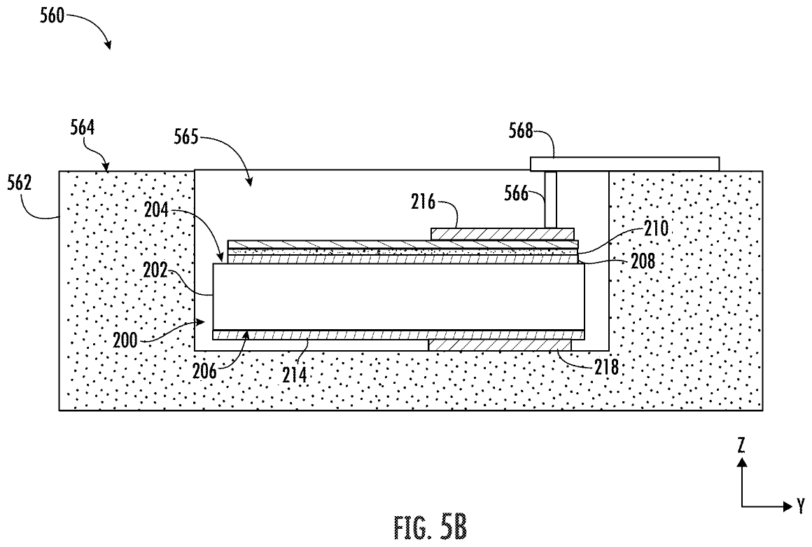

FIGS. 5A and 5B each illustrate an embedded capacitor assembly 560 including a capacitor 300 embedded in a circuit board substrate 562 according to aspects of the present disclosure. The circuit board substrate 562 can be, e.g., a printed circuit board and can be formed from any suitable material such as FR4, polytetrafluoroethylene, or the like. The circuit board substrate 562 includes a mounting surface 564. The capacitor 300 can generally be configured similar to the capacitor 300 of FIGS. 3A and 3B, although in other embodiments, the capacitor embedded in the embedded capacitor assembly 560 could be configured similar to the capacitor 100 of FIG. 1 or the capacitor 200 of FIGS. 2A-2C.

The capacitor can be at least partially embedded within the circuit board substrate 562 of the embedded capacitor assembly 560. As shown in FIG. 5A, a first via 566 can extend from the first terminal 316 of the capacitor 300 toward the mounting surface 564 and connect to a first conductive layer 568 formed over the mounting surface 564. The first via 566 of the circuit board 560 can electrically connect the first terminal 316 with the first conductive layer 568 of the circuit board 560.

Referring still to FIG. 5A, a second via 570 can extend from the second terminal 318 of the capacitor 300 toward the mounting surface 564 and connect to a second conductive layer 572 formed over the mounting surface 564. The second via 570 of the circuit board 560 can electrically connect the second terminal 318 with the second conductive layer 572 of the circuit board 560.

Alternatively, the vias 566, 570 can extend toward the mounting surface 564 and connect with one or more intermediate layers (e.g., embedded within the circuit board substrate 562), which can in turn be electrically connected with the first conductive layer 568 and/or the second conductive layer 572. The first via 566 can form at least a portion of an electrical connection between the first terminal 316 of the capacitor 300 and the first conductive layer 568 of the circuit board 560. Similarly, the second via 570 can form at least a portion of an electrical connection between the second terminal 318 of the capacitor 300 and the second conductive layer 572 of the circuit board 560. As such, the conductive layers 568, 572 can be used to facilitate electrical connections with the capacitor 300. However, it should be understood that, in other embodiments, one or both of the terminals 316, 318 can be exposed along the mounting surface 564. In such an embodiment, the circuit board 560 can be free of one or both of the vias 566, 570.

As previously stated, the capacitor embedded in the circuit board substrate 562 could be configured similar to the capacitor 100 of FIG. 1 or the capacitor 200 of FIGS. 2A-2C. For example, referring to FIG. 5B, where the embedded capacitor is configured similarly to the capacitor 200 described herein, the embedded capacitor assembly 560 may include one via and one conductive layer on the mounting surface 564, such as via 566 that extends between the first terminal 216 and conductive layer 568 on the mounting surface 564. In such embodiments, via 570 may extend between the second terminal 218 and conductive layer 572 disposed at another location within or on the circuit board 560. More particularly, as shown in FIG. 5B, the mounting surface 564 can have an opening 565 that is recessed into the circuit board substrate 562. To minimize its height profile on the board, the capacitor 200 can be embedded within the opening 565 and attached to the circuit board substrate 562 using known techniques. For example, using known techniques, one or more vias can connect one or more terminals of the capacitor 200 with one or more conductive traces of the circuit board substrate 562, as further described herein.

Referring to FIG. 5B, the first terminal 216 and the second terminal 218 are formed over opposite surfaces of the substrate 202 of the illustrated capacitor 200. For example, the first terminal 216 is formed over the first surface 204, which may be an upper surface of the substrate 202, and the second terminal 218 is formed over the second surface 206, which may be a lower surface of the substrate 202. As shown in FIG. 5B, a via 566 can extend from the first terminal 216 of the capacitor 200 toward the mounting surface 564 and connect to a conductive layer 568 formed over the mounting surface 564. The via 566 of the embedded capacitor assembly 560 can electrically connect the first terminal 216 with the first conductive layer 568, which may be, e.g., a conductive trace of the circuit board substrate 562. Alternatively, the via 566 can extend toward the mounting surface 564 and connect with one or more intermediate layers (e.g., embedded within the circuit board substrate 562), which can in turn be electrically connected with the conductive layer 568. The via 566 can form at least a portion of an electrical connection between the first terminal 216 of the capacitor 200 and the conductive layer 568 of the embedded capacitor assembly 560. However, it should be understood that, in other embodiments, the terminal 216 can be exposed along the mounting surface 564. In such an embodiment, the embedded capacitor assembly 560 can be free of the via 566.

In some embodiments, the circuit board substrate 562 can include multiple conductive layers 568, 572, e.g., multiple conductive traces, and the capacitor 200 can include multiple terminals 216 and/or 218 exposed along the first surface 204. A plurality of vias 566, 570 can extend from the terminals to the conductive layers of the circuit board substrate 562, e.g., at least one via can extend from a respective one terminal 216, 218 of the capacitor 200 to a respective one conductive layer 568, 572 of the circuit board substrate 562.

The degree of which the capacitor is embedded depends on a variety of factors, such as the thickness of the circuit board substrate 562, the depth of the opening 565, the thickness of the capacitor 100, 200, 300, etc. The thickness of the circuit board substrate 562 (not including the attached electronic components) may be, in some embodiments, from about 0.1 to about 5 millimeters, in some embodiments, from about 0.2 to about 3 millimeters, and in some embodiments, from about 0.4 to about 1.5 millimeters. Thus, depending on the particular thicknesses employed, the capacitor may be embedded so that the exposed surfaces of the first terminal 116, 216, 316 are substantially coplanar with or below the mounting surface 564 of the circuit board substrate 562. For instance, the capacitor 100, 200, 300 can be embedded and enclosed within the opening 565 of the circuit board substrate 562. Alternatively, the capacitor 100, 200, 300 may be embedded so that the exposed surfaces of the first terminal 116, 216, 316 extend slightly above the mounting surface 564 of the circuit board substrate 562. Regardless, by at least partially embedding the capacitor 100, 200, 300 in the circuit board substrate 562, the height profile or thickness occupied by the capacitor is decreased and may be controlled depending on the desired use.

It should be understood that various other electronic components may also be mounted onto the circuit board substrate 562 as is well known in the art and that a single capacitor is shown in FIGS. 5A and 5B only for purposes of illustration.

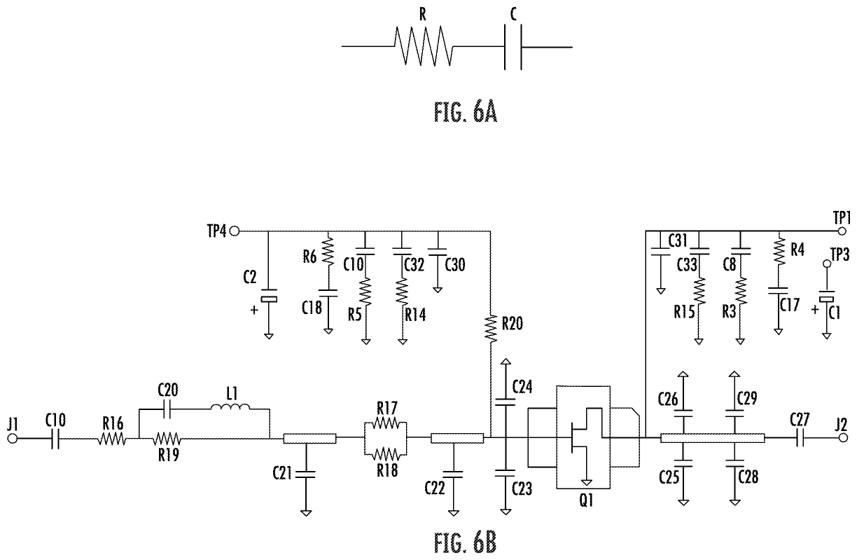

Turning to FIGS. 6A and 6B, electrical diagrams are provided depicting the capacitors 100, 200, 300 described herein. As shown in FIG. 6A, each capacitor 100, 200, 300 comprises a resistor R and capacitor C arranged in series with one another. Referring to FIG. 6B, one or more of the exemplary capacitors 100, 200, 300 described with respect to FIGS. 1 through 3B may be used in various electrical systems or devices. For example, FIG. 6B illustrates an exemplary high electron mobility transistor (HEMT) according to aspects of the present subject matter. On the left side of the electrical diagram shown in FIG. 6B, a plurality of capacitors as described herein, represented as R6/C18, R5/C10, and R14/C32, are arranged in a negative bias bank, while on the right side, a plurality of capacitors as described herein, represented as R15/C33, R3/C8, and R4/C17, are arranged in a Vdd bias bank. As previously stated, MOS capacitors as described herein, e.g., capacitors 100, 200, 300 described above, can have increased ESR, which can reduce the number of components in a bias bank such as the bias banks illustrated in the HEMT of FIG. 6B, which, in turn, can increase the reliability, reduce the size, and improve performance of the device. The HEMT represented in FIG. 6B is by way of example only; it will be appreciated that the capacitors 100, 200, 300 described herein may used in a variety of applications.

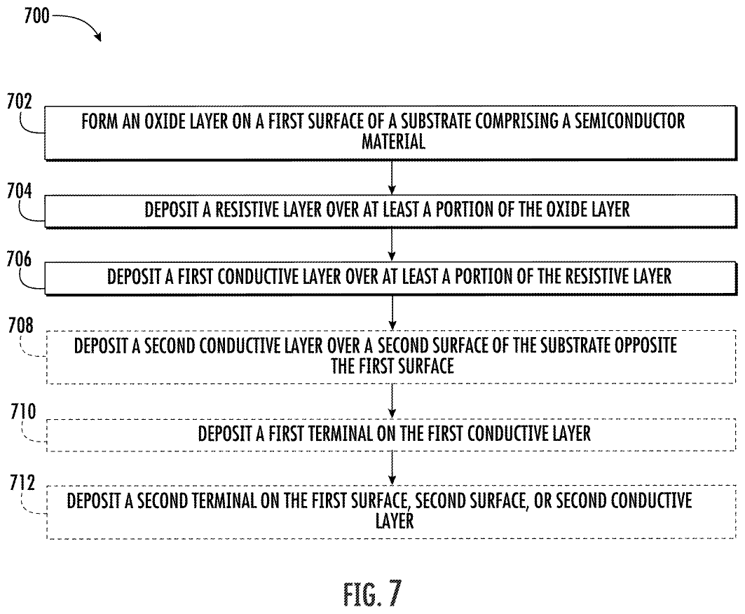

Referring now to FIG. 7, aspects of the present subject matter are directed to a method 700 for forming a capacitor such as described herein. In general, the method 700 will be described herein with reference to the capacitor 200 of FIGS. 2A through 2C. However, it should be appreciated that the disclosed method 700 may be implemented with any suitable capacitor. In addition, although FIG. 7 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present subject matter.

The method 700 can include (702) forming an oxide layer 208 over a first surface 204 of a substrate 202 comprising a semiconductor material. For example, the oxide layer 208 can be grown in situ on the substrate 202. Lithography (e.g., photolithography) techniques can be used to define the shape of the oxide layer 208. For instance, for a capacitor 300 having an oxide layer 308 as described with respect to FIGS. 3A and 3B, portions of the oxide layer 308 can be removed through etching such that the oxide layer 308 is located within the first portion 326 of the first surface 304 of the substrate 302.

The method 700 can include (704) depositing a resistive layer 210 over at least a portion of the oxide layer 208. The resistive layer 210 can be contained within a perimeter 209 of the oxide layer 208. The resistive layer 210 can be free of direct contact and/or direct electrical connection with the substrate 202. The resistive layer 210 can have a thickness less than about 10 microns. The resistive layer 210 can be formed from tantalum nitride, chromium silicon, or other suitable resistive material such as described herein.

The method 700 can include (706) depositing a first conductive layer 212 over at least a portion of the resistive layer 210. The first conductive layer 212 can be contained within a perimeter 211 of the resistive layer 210. The first conductive layer 212 can be free of direct contact and/or direct electrical connection with the oxide layer 208 and/or the substrate 202.

The method 700 can optionally include (708) depositing a second conductive layer 214 over at least a portion of a second surface 206 of the substrate 202. The second surface 206 of the substrate 202 can be opposite the first surface 204 of the substrate 202.

The method 700 can optionally include (710) depositing a first terminal 216 on the first conductive layer 212. For instance, in some embodiments, a separate first terminal 216 may be formed over the first conductive layer 212, but in other embodiments, the first conductive layer 212 may form the first terminal 216. The method can optionally include (712) depositing a second terminal 218 such that at least the substrate 202, the oxide layer 208, and the resistive layer 210 are disposed between the first conductive layer 212 and the second terminal 218. For example, as described herein, in some embodiments the second conductive layer 214 may form the second terminal 218. In other embodiments, the second terminal 218 may be deposited on the second conductive layer 214 such that the substrate 202, the oxide layer 208, the resistive layer 210, and the second conductive layer 214 are disposed between the first conductive layer 212 and the second terminal 218.

Alternatively, in some embodiments such as described with respect to the capacitor 300, the second terminal 318 may be deposited on the first surface 304 of the substrate 302 such that the second terminal 318 is connected with the substrate 302. As such, both the first terminal 316 and the second terminal 318 are formed over the first surface 304 of the substrate 302, and both of the first terminal 316 and the second terminal 318 can be exposed along the first surface 304 of the substrate 302 for surface mounting the capacitor 300. In any event, the pair of terminals 216, 218 or 316, 318 are connected to various layers or substrate of the respective capacitor 200, 300 such that a resistor and a capacitor are formed in series with one another.

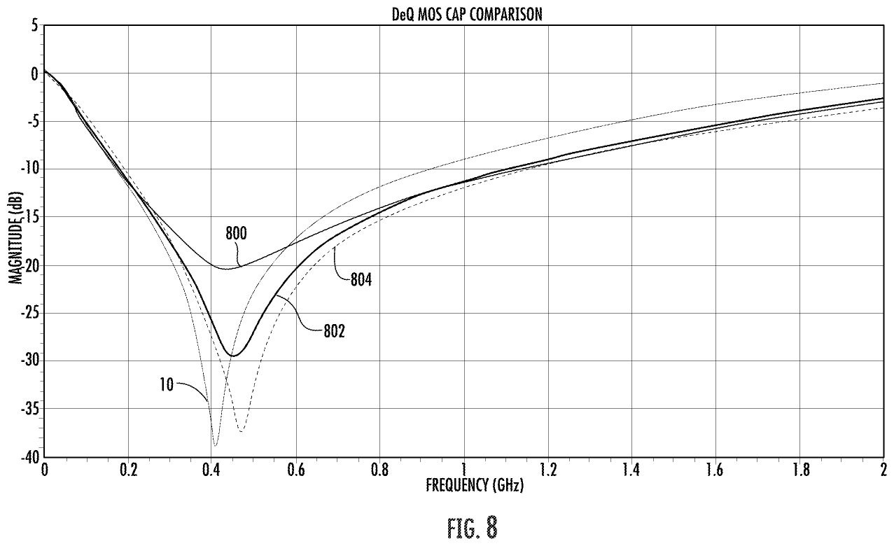

Turning now to FIG. 8, a graph is provided of insertion loss (S₂₁) for a variety of capacitors 800, 802, 804 formed as described herein and a MOS capacitor 10 formed according to a known or standard design. That is, a first capacitor 800, a second capacitor 802, and a third capacitor 804 each are MOS capacitors including a resistive layer, and the standard MOS capacitor 10 does not include a resistive layer.

The first capacitor 800 has a resistive layer and a first conductive layer (such as a resistive layer 110, 210, 310 and a first conductive layer 112, 212, 312 as described herein) such that, of the three capacitors 800, 802, 804, the first capacitor 800 has the largest ratio of the area of the resistive layer to the area of the first conductive layer. The third capacitor 804 has a resistive layer and a first conductive layer (such as a resistive layer 110, 210, 310 and a first conductive layer 112, 212, 312 as described herein) such that, of the three capacitors 800, 802, 804, the third capacitor 804 has the smallest ratio of the area of the resistive layer to the area of the first conductive layer. The second capacitor 802 has a resistive layer and a first conductive layer (such as a resistive layer 110, 210, 310 and a first conductive layer 112, 212, 312 as described herein) such that a ratio of the area of the resistive layer to the area of the first conductive layer is between such ratio for the first capacitor 800 and the third capacitor 804. As described herein, e.g., with respect to FIG. 2D, the area of the resistive layer of each capacitor 800, 802, 804 is the product of the length L_{R} of the respective resistive layer and the width WR of the respective resistive layer, and the area of the first conductive layer is the product of the length L_{C1} of the respective first conductive layer and the width W_{C1} of the respective first conductive layer.

The Q factor of each capacitor 800, 802, 804, 10 is indicated by the resonance point of the insertion loss of the respective capacitor. As shown in FIG. 8, for a respective capacitor 800, 802, 804, 10, its Q factor decreases as the ratio of the area of the resistive layer to the area of the first conductive layer increases. Thus, the first capacitor 800 has the lowest Q factor, the second capacitor 802 has the next lowest Q factor, the third capacitor 804 has the third lowest Q factor, and the standard MOS capacitor 10 has the highest Q factor of the four capacitors of FIG. 8.

Accordingly, the resistive layer 112, 212, 312 of the various embodiments described herein can lower the Q factor of a respective capacitor. As described above, a lower Q factor can broaden the frequency response of the capacitor, which can improve the performance of bias lines in active radiofrequency (RF) devices, e.g., by providing filtered voltage to the active RF device. Additionally, or alternatively, a broadened frequency response can enhance the performance of MOS capacitors in RF shunt applications and noise filtering applications. Other benefits and advantages may also be realized from reducing or lowering the Q factor of capacitors as described herein.

### Applications

The capacitor described herein is useful in a variety of applications. The capacitor may be particularly useful in devices that process wideband radiofrequency signals, as the capacitor exhibits excellent performance at high frequencies, such as frequencies of 20 GHz or higher. Example devices include mobile devices (e.g., cell phones, tables etc.), cell phone towers, Receiver Optical Sub Assemblies (ROSA), Transmission Optical Sub Assembly (TOSA), and other RF communication devices. Such devices may be particularly useful in military and space applications.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A capacitor comprising:
a substrate comprising a semiconductor material;
an oxide layer formed over a first surface of the substrate;
a resistive layer formed over at least a portion of the oxide layer; and
a first conductive layer formed over at least a portion of the resistive layer.

2. The capacitor of claim 1, further comprising:
a second conductive layer formed over a second surface of the substrate, the second surface of the substrate opposite the first surface of the substrate.

3. The capacitor of claim 2, further comprising:
a first terminal connected with the first conductive layer; and
a second terminal connected with the second conductive layer.

4. The capacitor of claim 1, wherein the resistive layer has a thickness less than about 10 microns.

5. The capacitor of claim 1, wherein the resistive layer is formed from tantalum nitride.

6. The capacitor of claim 1, wherein the resistive layer is formed from chromium silicon.

7. The capacitor of claim 1, further comprising:
a first terminal connected with the first conductive layer; and
a second terminal connected with the first surface of the substrate, wherein the oxide layer is connected in series between the substrate and the first conductive layer to form a capacitor between the first terminal and the second terminal.

8. The capacitor of claim 7, wherein each of the first terminal and the second terminal are exposed along the first surface of the substrate for surface mounting the capacitor.

9. The capacitor of claim 7, wherein the second terminal comprises an electrically conductive material that directly contacts the surface of the substrate.

10. The capacitor of claim 1, wherein the semiconductor material of the substrate comprises silicon.

11. The capacitor of claim 1, wherein the oxide layer comprises silicon oxide.

12. The single layer capacitor of claim 1, wherein a ratio of an area of the resistive layer to an area of the first conductive layer is at least about 1.5:1.

13. The single layer capacitor of claim 1, wherein a ratio of an area of the resistive layer to an area of the first conductive layer is at least about 10:1.

14. The single layer capacitor of claim 1, wherein a ratio of an area of the resistive layer to an area of the first conductive layer is at least about 20:1.

15. A capacitor comprising:
a substrate comprising a semiconductor material, the substrate having a first surface opposite a second surface;
an oxide layer formed over the first surface of the substrate;
a resistive layer formed over at least a portion of the oxide layer;
a first conductive layer formed over at least a portion of the resistive layer; and
a second conductive layer formed over at least a portion of the second surface of the substrate,
wherein the resistive layer has a thickness less than about 10 microns.

16. The capacitor of claim 15, further comprising:
a first terminal connected with the first conductive layer; and
a second terminal connected with the second conductive layer.

17. The capacitor of claim 15, wherein at least one of the first conductive layer and the second conductive layer is one terminal of a pair of terminals.

18. The capacitor of claim 15, further comprising:
a first terminal connected with the first conductive layer; and
a second terminal connected with the first surface of the substrate.

19. An embedded capacitor assembly comprising:
a circuit board substrate having a mounting surface; and
a capacitor at least partially embedded within the circuit board substrate, the capacitor comprising:
a substrate comprising a semiconductor material and having a first surface opposite a second surface,
an oxide layer formed over the first surface of the substrate,
a resistive layer formed over at least a portion of the oxide layer,
a conductive layer formed over at least a portion of the resistive layer.

20. The embedded capacitor assembly of claim 19, the capacitor further comprising:
a first terminal connected with the conductive layer, and
a second terminal connected with the substrate,
wherein the first terminal and the second terminal are each formed over the first surface of the substrate, and
wherein the second terminal is free of electrical connection to the oxide layer.

21. The embedded capacitor assembly of claim 20, the capacitor further comprising:
at least one via connected with the one of the first terminal or the second terminal, the at least one via extending toward the mounting surface of the circuit board substrate.

22. The embedded capacitor assembly of claim 21, wherein the circuit board substrate further comprises a conductive layer, and wherein the at least one via is connected with the conductive layer of the circuit board substrate.
